(19) United States
(12) Patent Application Publication
(10) Pub. No.: US 2018/0306638 A1
(43) Pub. Date: Oct. 25, 2018

(54) OPTICAL SENSOR

(71) Applicant: Murata Manufacturing Co., Ltd., Nagaokakyo-shi (JP)

(72) Inventor: Hiroki ISHIKAWA, Nagaokakyo-shi (JP)

(21) Appl. No.: 15/826,749

(22) Filed: Nov. 30, 2017

(30) Foreign Application Priority Data
Apr. 21, 2017 (JP) 2017-084462

(51) Int. Cl. G01J 1/02; H01L 31/02; H01L 31/0203; H01L 31/0216; H01L 31/0232; H01L 31/147; G01J 1/44; G01J 1/04

(52) U.S. Cl. CPC G01J 1/0204; H01L 31/02005; H01L 31/02019; H01L 31/0203; H01L 31/02164; G01J 2001/446; H01L 31/147; G01J 1/44; G01J 1/0407; G01J 1/0403; G01J 1/0214; H01L 31/02325

(57) ABSTRACT

An optical sensor includes a substrate, a light emitting element, a light receiving element, and an electrical component. The light emitting element is mounted on a front surface of the substrate. The light receiving element is mounted on the front surface of the substrate and at a position different from that of the light emitting element. The electrical component is mounted on a back surface of the substrate. The electrical component is electrically connected to the light emitting element and the light receiving element. The electrical component is located at a position overlapping the light emitting element and the light receiving element in plan view.

### CROSS REFERENCE TO RELATED APPLICATIONS

This application claims the benefit of priority to Japanese Patent Application No. 2017-084462 filed on Apr. 21, 2017. The entire contents of this application are hereby incorporated herein by reference.

### BACKGROUND OF THE INVENTION

### 1. Field of the Invention

The present invention relates to an optical sensor including a light emitting element and a light receiving element.

### 2. Description of the Related Art

Generally, an optical sensor including a light emitting element that emits light to a measurement object and a light receiving element that receives light reflected by the measurement object, is known (see, for example, Japanese Unexamined Patent Application Publication No. 2011-180121). Japanese Unexamined Patent Application Publication No. 2011-180121 discloses a configuration in which, in addition to a light emitting element and a light receiving element, an integrated circuit component that is electrically connected to these elements is mounted on a substrate.

Meanwhile, in order to increase the detection sensitivity of the optical sensor, it is preferable to increase the light reception sensitivity of the light emitting element. On the other hand, in the optical sensor disclosed in Japanese Unexamined Patent Application Publication No. 2011-180121, since the light emitting element, the light receiving element, and the integrated circuit component are mounted on the front surface of the substrate, the area of the substrate tends to increase. In addition, when a light receiving element having a large light reception area is used in order to increase the light reception sensitivity, the size of the optical sensor increases.

### SUMMARY OF THE INVENTION

Preferred embodiments of the present invention provide optical sensors that are able to be reduced in size.

An optical sensor according to a preferred embodiment of the present invention includes a substrate; a light emitting element mounted on a front surface of the substrate; a light receiving element mounted on the front surface of the substrate; and an electrical component mounted on a back surface of the substrate and electrically connected to the light emitting element and the light receiving element, and the electrical component is located at a position overlapping the light emitting element and the light receiving element, in plan view.

An optical sensor according to a preferred embodiment of the present invention further includes a frame provided at the front surface side of the substrate and configured to shield light between the light emitting element and the light receiving element; and a transparent resin portion covering the light emitting element and the light receiving element.

An optical sensor according to a preferred embodiment of the present invention further includes an optical waveguide plate provided at the front surface side of the substrate and covering the light emitting element and the light receiving element, and the optical waveguide plate includes a light emission side optical waveguide that guides light from the light emitting element to the outside, and a light reception side optical waveguide that guides external light to the light receiving element.

An optical sensor according to a preferred embodiment of the present invention further includes a bottom portion provided at the back surface side of the substrate, covering the electrical component, and made of a resin material; and an electrode terminal provided on a back surface of the bottom portion and electrically connected to the electronic component.

According to a preferred embodiment of the present invention, the light emitting element and the light receiving element are mounted on the front surface of the substrate, the electrical component is mounted on the back surface of the substrate, and the electrical component is located at the position overlapping the light emitting element and the light receiving element in plan view. Thus, the area of the substrate is able to be smaller than in a case where the electrical component, the light emitting element, and the light receiving element are located at different positions on the front surface of the substrate, to reduce the size of the entire optical sensor.

According to a preferred embodiment of the present invention, the frame, which shields light between the light emitting element and the light receiving element, is provided at the front surface side of the substrate, and thus, the frame is able to prevent light from the light emitting element from directly reaching the light receiving element. In addition, the light emitting element and the light receiving element are covered with the transparent portion. Thus, it is possible to emit the light from the light emitting element through the transparent portion to the outside. In addition, it is possible to enable external light to reach the light receiving element through the transparent portion.

According to a preferred embodiment of the present invention, the optical waveguide plate, which covers the light emitting element and the light receiving element, is provided at the front surface side of the substrate. Thus, it is possible to emit the light from the light emitting element through the light emission side optical waveguide of the optical waveguide plate to the outside. In addition, it is possible to enable external light to reach the light receiving element through the light reception side optical waveguide of the optical waveguide plate.

According to a preferred embodiment of the present invention, the bottom portion, which is made of a resin material, covers the electrical component at the back surface side of the substrate, and thus, it is possible for the back surface of the bottom portion to be a flat surface. Therefore, it is possible to mount the optical sensor on the mounting substrate without interfering with the electrical component. It is possible to easily join an electrode terminal provided on the back surface of the bottom portion to an electrode at the mounting substrate side.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a perspective view showing an optical sensor according to a first preferred embodiment of the present invention.

FIG. 2 is a perspective view showing a state in which the optical sensor in FIG. 1 is turned upside down.

FIG. 3 is a plan view showing the optical sensor in FIG. 1.

FIG. 4 is a cross-sectional view of the optical sensor taken along the line IV-IV in FIG. 3.

FIG. 5 is a block diagram showing the configuration of an electrical component.

FIG. 6 is a perspective view showing an optical sensor according to a second preferred embodiment of the present invention.

FIG. 7 is a plan view showing the optical sensor in FIG. 6.

FIG. 8 is a cross-sectional view of the optical sensor taken along the line VIII-VIII in FIG. 7.

FIG. 9 is a perspective view showing an optical sensor according to a third preferred embodiment of the present invention.

FIG. 10 is a plan view showing the optical sensor in FIG. 9.

FIG. 11 is a cross-sectional view of the optical sensor taken along the line XI-XI in FIG. 10.

FIG. 12 is a perspective view showing an optical sensor according to a modification of a preferred embodiment of the present invention.

FIG. 13 is a plan view showing the optical sensor in FIG. 12.

FIG. 14 is a cross-sectional view of the optical sensor taken along the line XIV-XIV in FIG. 13.

### DETAILED DESCRIPTION OF THE PREFERRED EMBODIMENTS

Hereinafter, optical sensors according to preferred embodiments of the present invention will be described in detail with reference to the accompanying drawings with the case in which various preferred embodiments of the present invention are applied to a pulse wave sensor, as an example.

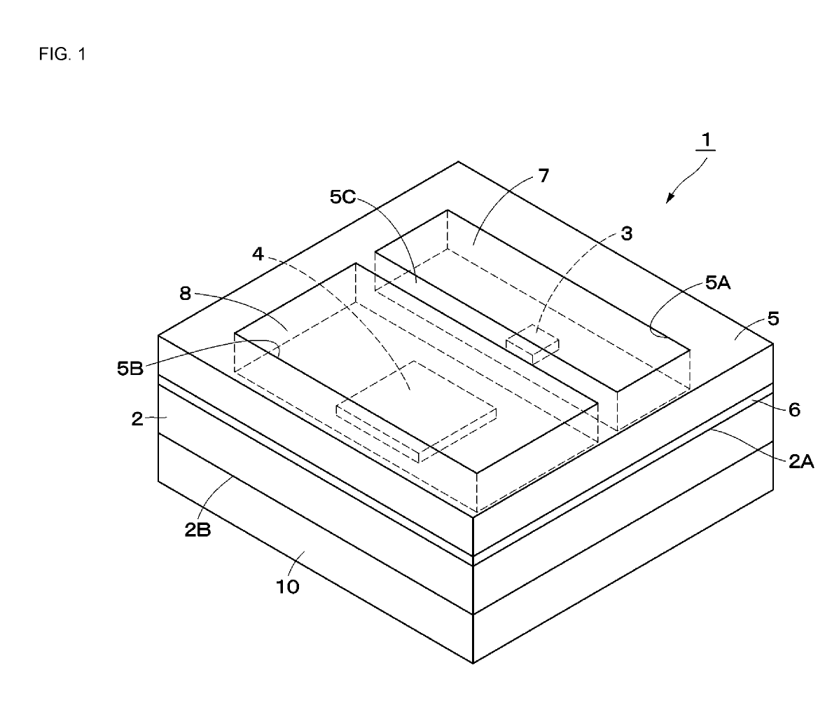

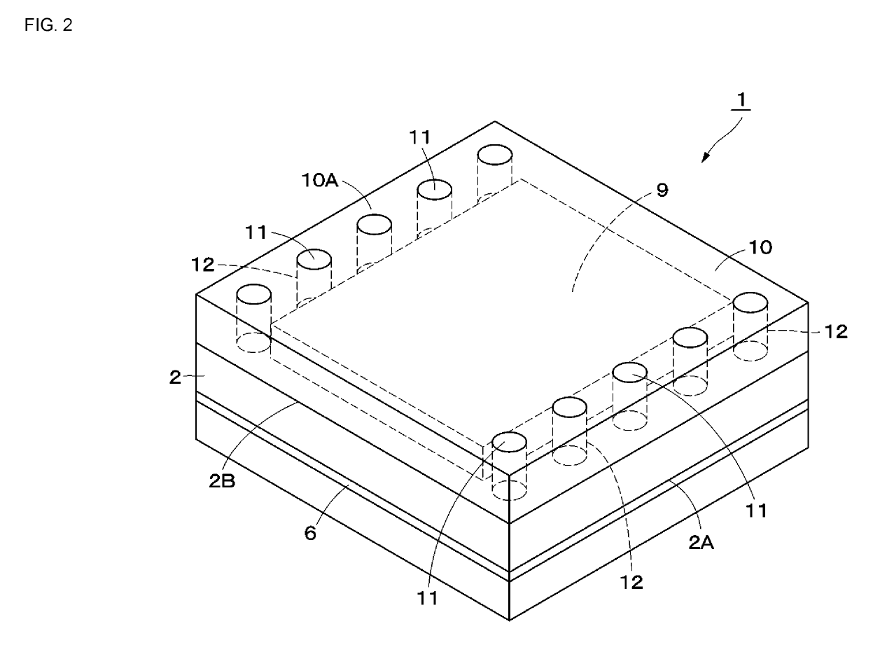

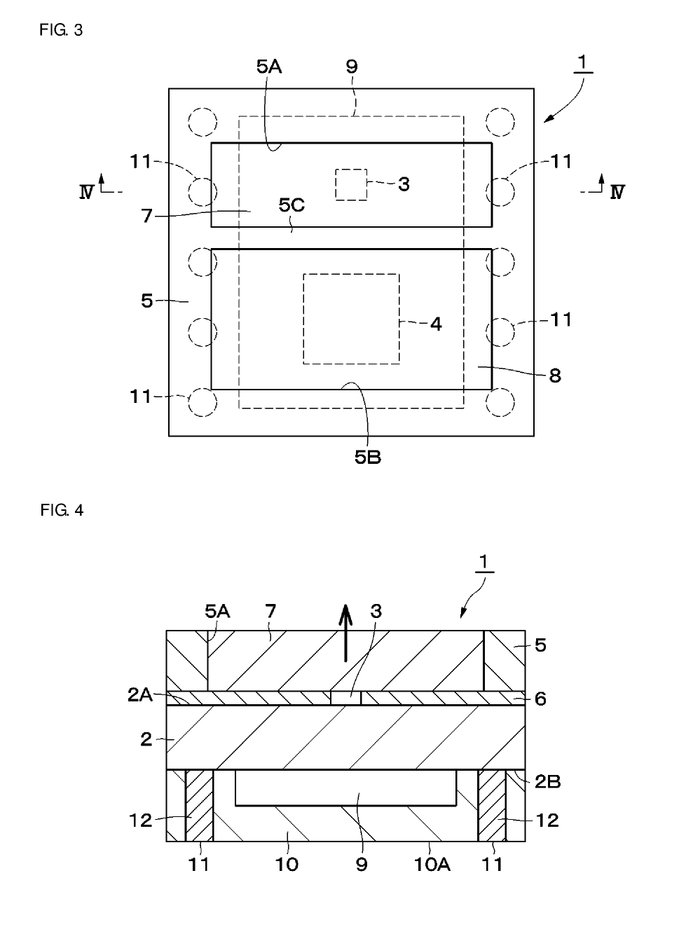

FIGS. 1 to 4 show an optical sensor 1 according to a first preferred embodiment of the present invention. The optical sensor 1 detects a photoplethysmographic signal (pulse wave signal) corresponding to a pulse, from a living body as a measurement object, for example. The optical sensor 1 includes a substrate 2, a light emitting element 3, a light receiving element 4, and an electrical component 9.

The substrate 2 is preferably a plate made of an insulating material. For example, a wiring substrate or a ceramic substrate is used as the substrate 2. The substrate 2 may be a multilayer substrate in which a plurality of electrode layers and a plurality of insulating layers are alternately laminated. The light emitting element 3 and the light receiving element 4 are mounted as optical components on a front surface 2A (a principal surface at one side) of the substrate 2. The electrical component 9 is mounted on a back surface 2B (a principal surface at the other side) of the substrate 2. Thus, the substrate 2 is a double-sided mounting substrate. Among the optical components (the light emitting element 3, the light receiving element 4) and the electrical component 9, only the optical components are mounted on the front surface 2A of the substrate 2.

The light emitting element 3 is preferably defined by, for example, a light emitting diode (LED), a laser diode (LD), a vertical-cavity surface-emitting laser (VCSEL), a resonant type LED, or other suitable element. The light emitting element 3 preferably emits light in the 500 nm to 1000 nm band, for example. The light emitting element 3 is mounted on the front surface 2A of the substrate 2 preferably using a joining method, such as die-bonding and wire-bonding, for example. The light emitting element 3 is electrically connected to the electrical component 9.

The light receiving element 4 is preferably defined by, for example, a photodiode (PD) or other suitable structure. The light receiving element 4 is located on the front surface 2A of the substrate 2 and at a position that is different from that of the light emitting element 3 and adjacent to the light emitting element 3. The light receiving element 4 is electrically connected to the electrical component 9.

The light receiving element 4 (photoelectrically) converts a received optical signal to an electrical signal, such as a current signal, and outputs the electrical signal. Specifically, the light receiving element 4 receives light that is emitted from the light emitting element 3 and reflected by the living body, and converts the received light to a detection signal S composed of an electrical signal. The light receiving element 4 outputs the detection signal S toward the electrical component 9. The light receiving element 4 is mounted on the front surface 2A of the substrate 2 preferably using a joining method, such as die-bonding and wire-bonding, for example. The light receiving element 4 may be defined by using a phototransistor, for example.

A frame 5 is provided at the front surface 2A side of the substrate 2 and shields light between the light emitting element 3 and the light receiving element 4. A joint layer 6 preferably made of, for example, a transparent resin material is provided between the frame 5 and the substrate 2. The frame 5 is fixed to the substrate 2 by the joint layer 6. The frame 5 is preferably, for example, black and made of a non-transparent resin material in order to block the light from the light emitting element 3.

The frame 5 individually surrounds the light emitting element 3 and the light receiving element 4. Thus, the frame 5 includes a housing hole 5A that is located at a position corresponding to the light emitting element 3 and penetrates in the thickness direction, and a housing hole 5B that is located at a position corresponding to the light receiving element 4 and penetrates in the thickness direction. The light emitting element 3 is housed in the housing hole 5A. The light receiving element 4 is housed in the housing hole 5B. In addition, the frame 5 includes a light shielding wall 5C located between the light emitting element 3 and the light receiving element 4. The light shielding wall 5C prevents the light from the light emitting element 3 from directly reaching the light receiving element 4. The opening area of the housing hole 5A is sufficiently larger than the light emitting surface of the light emitting element 3 such that the light from the light emitting element 3 is not shielded by the frame 5. The opening area of the housing hole 5B is sufficiently larger than the light receiving surface of the light receiving element 4 in order to allow the reflected light from the living body to reach the light receiving element 4 as much as possible.

Transparent portions 7 and 8 cover the light emitting element 3 and the light receiving element 4, respectively. The transparent portions 7 and 8 are preferably made of a resin material (transparent resin material) that allows the light from the light emitting element 3 and reflected light from the measurement object to pass therethrough. The transparent portion 7 is located within the housing hole 5A of the frame 5 and covers the light emitting surface side of the light emitting element 3. The transparent portion 8 is located within the housing hole 5B of the frame 5 and covers the light receiving surface side of the light receiving element 4.

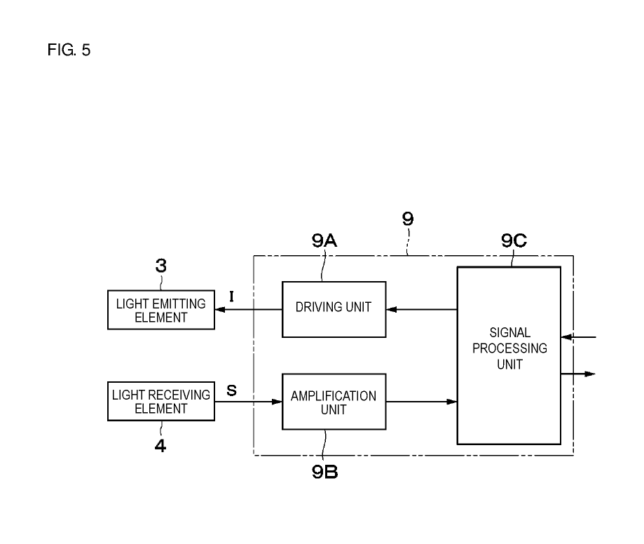

The electrical component 9 is defined by, for example, an integrated circuit component (IC component). As shown in FIG. 5, the electrical component 9 includes, for example, a driving unit 9A, an amplification unit 9B, and a signal processing unit 9C. The electrical component 9 is mounted on the back surface 2B of the substrate 2 and located at a position overlapping the light emitting element 3 and the light receiving element 4 in plan view. Thus, the electrical component 9, and the light emitting element 3 and the light receiving element 4 are stacked in the height direction (the thickness direction of the substrate 2) with the substrate 2 interposed therebetween.

The input side of the driving unit 9A is connected to the signal processing unit 9C. The output side of the driving unit 9A is connected to the light emitting element 3. The driving unit 9A supplies a driving current I to the light emitting element 3 on the basis of a driving signal from the signal processing unit 9C. The driving current I is pulse-modulated, for example, at a predetermined frequency on the basis of the driving signal from the signal processing unit 9C. Accordingly, the light emitting element 3 emits light in a blinking manner. The driving unit 9A may supply a continuous driving current I to the light emitting element 3. In this case, the light emitting element 3 continuously emits light.

The input side of the amplification unit 9B is connected to the light receiving element 4. The output side of the amplification unit 9B is connected to the signal processing unit 9C. The amplification unit 9B is preferably, for example, a transimpedance amplifier (TIA), and converts the detection signal S from the light receiving element 4, which is defined by the current signal, to a voltage signal and amplifies the voltage signal. A filter that performs noise removal and other filtering functions may be provided between the amplification unit 9B and the signal processing unit 9C.

The output side of the signal processing unit 9C is connected to the driving unit 9A. The input side of the signal processing unit 9C is connected to the amplification unit 9B. In addition, the signal processing unit 9C is connected to the outside via a mounting substrate (not shown).

The signal processing unit 9C preferably includes, for example, a DA converter (DAC) and an AD converter (ADC). The signal processing unit 9C converts an externally inputted driving signal from a digital signal to an analog signal by the DA converter. The signal processing unit 9C converts the detection signal S inputted from the light receiving element 4 via the amplification unit 9B, from an analog signal to a digital signal by the AD converter. The electrical component 9 is not necessarily a single component. Thus, for example, the driving unit 9A, the amplification unit 9B, and the signal processing unit 9C may be individual electrical components.

A bottom portion 10 is provided at the back surface 2B side of the substrate 2 and covers the electrical component 9. The bottom portion 10 is preferably made of an insulating resin material. The bottom portion 10 includes a back surface 10A (bottom surface) that is a flat surface. A plurality of electrode terminals 11 are provided in the back surface 10A. To form the bottom portion 10, in a state where the electrical component 9 and conductor pins 12 are mounted on the back surface 2B of the substrate 2, a resin material having fluidity is applied so as to cover the electrical component 9. By curing the resin material, the bottom portion 10 is provided.

The electrode terminals 11 are exposed on the back surface 10A of the bottom portion 10. The electrode terminals 11 are electrically connected, for example, to the signal processing unit 9C of the electrical component 9. Specifically, the conductor pins 12, which are preferably made of, for example, a conductive metal, are mounted as columnar conductors on the back surface 2B of the substrate 2. The proximal end side of each conductor pin 12 is fixed to the substrate 2 and electrically connected to the electrical component 9. A distal end surface of each conductor pin 12 is exposed on the back surface 10A of the bottom portion 10 and defines the electrode terminal 11. Thus, each electrode terminal 11 inputs a driving signal from the outside to the signal processing unit 9C, and also outputs a detection signal from the signal processing unit 9C to the outside.

The optical sensor 1 according to the first preferred embodiment of the present invention has the configuration described above. Operation of the optical sensor 1 will be described below.

First, the optical sensor 1 is mounted on a mounting substrate (not shown) including a front surface on which an electrode is provided. At this time, the electrode terminals 11 of the optical sensor 1 are joined to the electrode on the mounting substrate. Accordingly, the electrical component 9 of the optical sensor 1 is connected to an external processing circuit on the mounting substrate.

The electrical component 9 supplies the driving current I to the light emitting element 3 on the basis of a driving signal from the external processing circuit. The light emitting element emits light to a living body as the measurement object in accordance with the driving current I. The light receiving element receives reflected light from the living body based on this light, and outputs the detection signal S. The electrical component 9 converts the detection signal S to a digital signal and outputs the digital signal to the external processing circuit.

At this time, the reflected light from the living body attenuates in accordance with a hemoglobin concentration. Thus, the external processing circuit is able to extract a photoplethysmographic signal corresponding to the pulse of the living body on the basis of the detection signal S based on the reflected light.

Meanwhile, as a method for increasing the detection sensitivity of the optical sensor 1, increasing the driving current I to be supplied to the light emitting element 3 or increasing the light reception sensitivity of the light receiving element 4 is conceivable. When the driving current I is increased, the power consumption of the optical sensor 1 increases. Thus, in order to increase the detection sensitivity, it is preferable to increase the light reception area of the light receiving element 4 to increase the light reception sensitivity of the light receiving element 4.

In the optical sensor disclosed in Japanese Unexamined Patent Application Publication No. 2011-180121, since the light emitting element, the light receiving element, and the integrated circuit component are mounted on the front surface of the substrate, the area of the substrate is increased. In addition, when the light reception area of the light receiving element is increased, the size of the entire optical sensor is further increased. Moreover, even when the light receiving element is integrated with the integrated circuit component, the light receiving element and a circuit portion that performs signal processing are provided at different positions on a semiconductor substrate. Thus, the integrated circuit component increases in size and becomes expensive. In addition, the light receiving element is made, for example, using a silicon substrate, the light emitting element is made, for example, using a gallium arsenide substrate. Since the semiconductor materials used for the light receiving element and the light emitting element are different from each other as described above, it is difficult to integrate the light emitting element, the light receiving element, and the integrated circuit component with each other.

On the other hand, the optical sensor 1 according to the present preferred embodiment includes a multilayer structure in which the light emitting element 3 and the light receiving element 4 are mounted on the front surface 2A of the substrate 2 and the electrical component 9 is mounted on the back surface 2B of the substrate 2. In addition, the electrical component 9 is located at a position overlapping the light emitting element 3 and the light receiving element 4 in plan view. Thus, it is possible to make the area of the substrate 2 smaller than in the case in which the electrical component 9, and the light emitting element 3, and the light receiving element 4 are located at different positions on the front surface 2A of the substrate 2, so that it is possible to reduce the size of the entire optical sensor 1. In addition, the light emitting element 3 and the light receiving element 4, and the electrical component 9 are preferably electrically connected via through holes (not shown) or other suitable structure extending in the thickness direction of the substrate 2. Thus, it is possible to reduce the length dimensions of connection lines connecting the light emitting element 3 and the light receiving element 4 to the electrical component 9 to be shorter than those in the case in which the electrical component 9, and the light emitting element 3 and the light receiving element 4 are located at different positions on the front surface 2A of the substrate 2, so that it is possible to reduce or prevent the influence of noise from the outside.

Since the frame 5, which shields light between the light emitting element 3 and the light receiving element 4, is provided at the front surface 2A side of the substrate 2, the light shielding wall 5C of the frame 5 is able to prevent the light from the light emitting element 3 from directly reaching the light receiving element 4. In addition, the light emitting element 3 and the light receiving element 4 are covered with the transparent portions 7 and 8, respectively. Thus, it is possible to emit the light from the light emitting element 3 through the transparent portion 7 toward the living body, and it is also possible to enable the reflected light from the living body to reach the light receiving element 4 through the transparent portion 8.

Since the bottom portion 10, which is preferably made of a resin material, is provided at the back surface 2B side of the substrate 2 so as to cover the electrical component 9, it is possible for the back surface 10A of the bottom portion 10 to be a flat surface. Thus, it is possible to mount the optical sensor on the mounting substrate without interference with the electrical component 9. Moreover, the electrode terminals 11 are provided in the back surface 10A of the bottom portion 10, the light emitting element 3, the light receiving element 4, and the electrical component 9 are provided together in one package so as to include the electrode terminals 11. Thus, it is possible to easily join the electrode terminals 11, which are provided in the back surface 10A of the bottom portion 10, to the electrode at the mounting substrate side.

In the first preferred embodiment, the frame 5, which shields light between the light emitting element 3 and the light receiving element 4, is provided at the front surface 2A side of the substrate 2. However, the present invention is not limited thereto. For example, the frame 5 may be omitted in a case in which it is possible to shield light between the light emitting element 3 and the light receiving element 4 at an application target side.

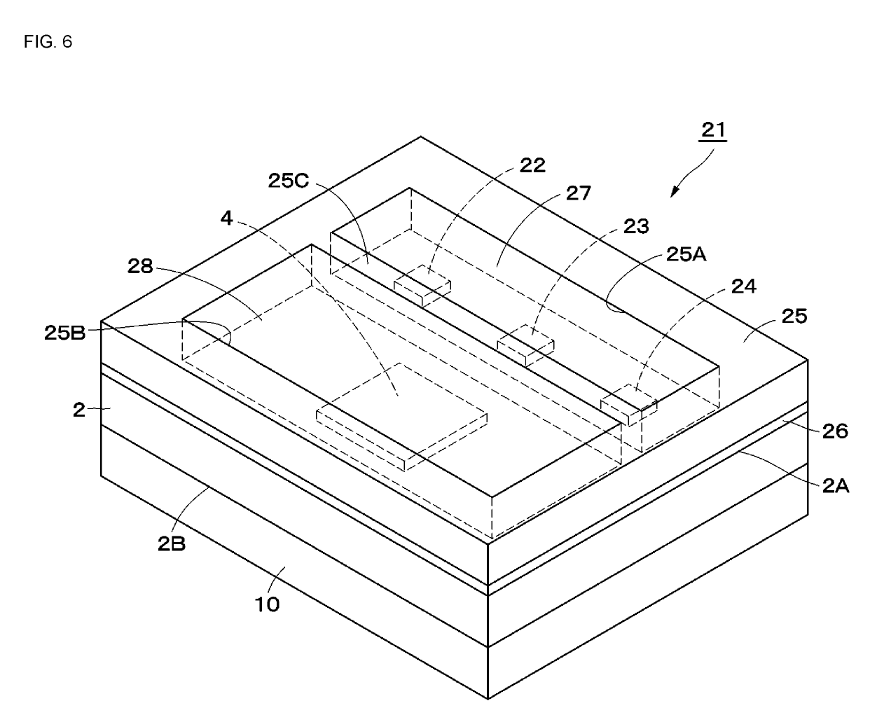

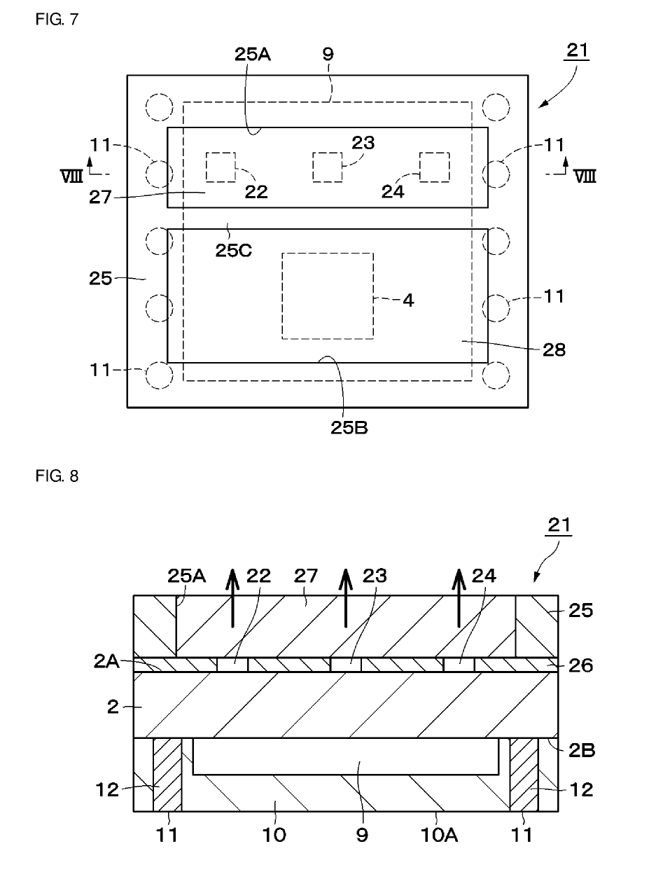

Next, a second preferred embodiment of the present invention will be described with reference to FIGS. 6 to 8. The feature of the second preferred embodiment that is different from the first preferred embodiment is that a plurality of light emitting elements are mounted on the front surface of the substrate. In the second preferred embodiment, the same components as those in the first preferred embodiment are designated by the same reference signs, and the description thereof is omitted.

An optical sensor 21 according to the second preferred embodiment is configured in substantially the same manner as the optical sensor 1 according to the first preferred embodiment. Thus, the optical sensor 21 includes a substrate 2, light emitting elements 22 to 24, a light receiving element 4, and an electrical component 9. The electrical component 9 is mounted on a back surface 2B of the substrate 2 and located at a position overlapping the light emitting elements 22 to 24 and the light receiving element 4 in plan view.

The light emitting elements 22 to 24 are configured in substantially the same manner as the light emitting element 3 according to the first preferred embodiment. The light emitting elements 22 to 24 may emit light in the same wavelength band, or may emit light in wavelength bands that are different from each other. The light emitting elements 22 to 24 are located on a front surface 2A of the substrate 2 and at positions that are different from that of the light receiving element 4 and adjacent to the light receiving element 4. The light emitting elements 22 to 24 are mounted on the front surface 2A of the substrate 2 preferably using a joining method, such as die-bonding and wire-bonding, for example. The light emitting elements 22 to 24 are electrically connected to the electrical component 9. The light emitting elements 22 to 24 emit light in a blinking manner or continuously emit light on the basis of a driving current supplied from the electrical component 9.

When the light emitting elements 22 to 24 emit light in the same wavelength band, the light emitting elements 22 to 24 preferably emit light together such that it is possible to increase an amount of light. When the light emitting elements 22 to 24 emit light in wavelength bands different from each other, the light emitting elements 22 to 24 preferably emit light at times different from each other such that reflected light having different characteristics is split.

A frame 25 is provided at the front surface 2A side of the substrate 2 and shields light between the light emitting elements 22 to 24 and the light receiving element 4. A joint layer 26 preferably made of, for example, a transparent resin material is provided between the frame 25 and the substrate 2. The frame 25 is configured in substantially the same manner as the frame 5 according to the first preferred embodiment. Preferably, the frame 25 surrounds the light emitting elements 22 to 24 together, and also surrounds the light receiving element 4. Thus, the frame 25 includes a housing hole 25A that is located at a position corresponding to the light emitting elements 22 to 24 and penetrates in the thickness direction, and a housing hole 25B that is located at a position corresponding to the light receiving element 4 and penetrates in the thickness direction. The light emitting elements 22 to 24 are housed in the housing hole 25A. The light receiving element 4 is housed in the housing hole 25B. In addition, the frame 25 includes a light shielding wall 25C located between the light emitting elements 22 to 24 and the light receiving element 4.

A transparent portion 27 covers the light emitting elements 22 to 24 together. A transparent portion 28 covers the light receiving element 4. The transparent portions 27 and 28 are preferably made of, for example, a resin material that allows the light from the light emitting elements 22 to 24 and reflected light from a measurement object to pass therethrough. The transparent portion 27 is located within the housing hole 25A of the frame 25 and covers the light emitting surface side of the light emitting elements 22 to 24. The transparent portion 28 is located within the housing hole 25B of the frame 25 and covers the light receiving surface side of the light receiving element 4.

Thus, in the second preferred embodiment, it is possible to achieve the same or substantially the same advantageous effects as those in the first preferred embodiment. In addition, in the second preferred embodiment, a plurality of (for example, three) light emitting elements 22 to 24 are provided on the substrate 2. Thus, when the light emitting elements 22 to 24 emit light in the same wavelength band, it is possible to increase the amount of light emitted to the measurement object, as compared to the case where one light emitting element is used, so that it is possible to increase the detection sensitivity of the optical sensor 21.

When the light emitting elements 22 to 24 emit light in wavelength bands different from each other, it is possible to detect signals of different characteristics together. In this case, noise cancelling is enabled, for example, by using one wavelength band for noise detection. In addition, it is also possible to produce various types of biological information, such as oxygen saturation, acceleration pulse wave, and pulse fluctuation, for example, by using detection signals in a plurality of wavelength bands.

In the second preferred embodiment, a plurality of the light emitting elements 22 to 24 and the one light receiving element 4 are mounted on the substrate 2. The present invention is not limited thereto. For example, one light emitting element and a plurality of light receiving elements may be mounted on the substrate, or a plurality of light emitting elements and a plurality of light receiving elements may be mounted on the substrate.

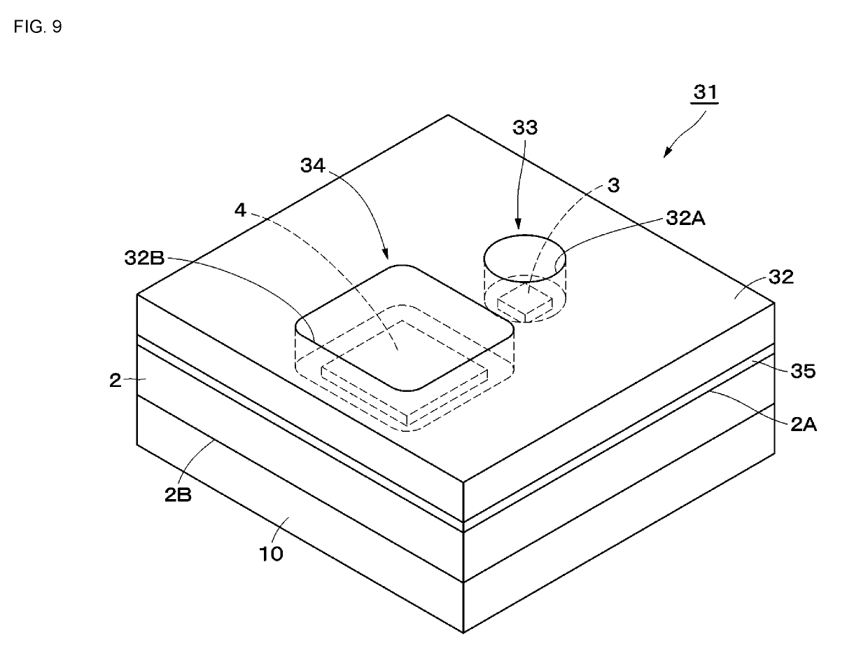

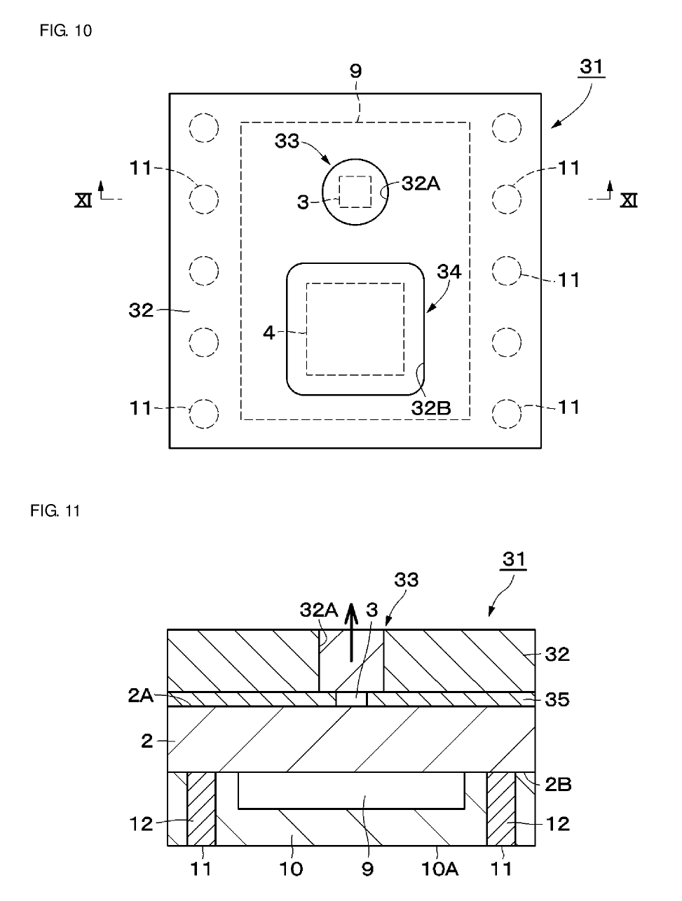

Next, a third preferred embodiment of the present invention will be described with reference to FIGS. 9 to 11. The feature of the third preferred embodiment that is different from the first preferred embodiment is that an optical waveguide plate that covers a light emitting element and a light receiving element is provided at the front surface side of a substrate. In the third preferred embodiment, the same components as those in the first preferred embodiment are designated by the same reference signs, and the description thereof is omitted.

An optical sensor 31 according to the third preferred embodiment is configured in substantially the same manner as the optical sensor 1 according to the first preferred embodiment. Thus, the optical sensor 31 includes a substrate 2, a light emitting element 3, a light receiving element 4, an electrical component 9, and an optical waveguide plate 32.

The optical waveguide plate 32 is provided at the front surface 2A side of the substrate 2 so as to cover the light emitting element 3 and the light receiving element 4. The optical waveguide plate 32 includes a light emission side optical waveguide 33 that guides light from the light emitting element 3 to a measurement object, and a light reception side optical waveguide 34 that guides reflected light from the measurement object to the light receiving element 4. The optical waveguide plate 32 preferably has a substantially flat plate shape made of a material having a low refractive index (e.g., a resin material). The optical waveguide plate 32 also has a light shielding property. The optical waveguide plate 32 limits a portion through which light passes.

The optical waveguide plate 32 includes through holes 32A and 32B provided at positions corresponding to the light emitting element 3 and the light receiving element 4. The through hole 32A preferably has a circular or substantially circular cross-sectional shape. The interior of the through hole 32A is filled with a material having a higher refractive index than the optical waveguide plate 32 (e.g., a resin material). The through hole 32B preferably has a square or substantially square cross-sectional shape, and the interior thereof is filled with a material having a high refractive index. Thus, in the optical waveguide plate 32, the light emission side optical waveguide 33 is provided at the position of the through hole 32A, and the light reception side optical waveguide 34 is provided at the position of the through hole 32B.

The light emission side optical waveguide 33 preferably has, for example, a larger opening area than the light emitting surface of the light emitting element 3 by about three times or less of the light emitting surface of the light emitting element 3. By setting the opening area of the light emission side optical waveguide 33 as appropriate, it is possible to adjust the numerical aperture of the light emission side optical waveguide 33. The light reception side optical waveguide 34 preferably has, for example, a larger opening area than the light receiving surface of the light receiving element 4.

A joint layer 35 preferably made of, for example, a transparent resin material is provided between the optical waveguide plate 32 and the substrate 2. The optical waveguide plate 32 is fixed to the substrate 2 using the joint layer 35.

Thus, in the third preferred embodiment, it is possible to achieve the same or substantially the same advantageous effects as those in the first preferred embodiment. In addition, in the third preferred embodiment, the optical waveguide plate 32, which covers the light emitting element 3 and the light receiving element 4, is provided at the front surface 2A side of the substrate 2. Thus, it is possible to emit the light from the light emitting element 3 through the light emission side optical waveguide 33 of the optical waveguide plate 32 to the measurement object. In addition, it is possible to cause the reflected light from the measurement object to reach the light receiving element 4 through the light reception side optical waveguide 34 of the optical waveguide plate 32.

As described above, the use of the optical waveguide plate 32 allows the portion through which light passes, to be controlled. For example, even when the spread angle of the light from the light emitting element 3 is large, it is possible to confine the light that is about to spread, by the light emission side optical waveguide 33. Thus, it is possible to reduce a spot diameter and emit a light beam having a high light emission density, toward the measurement object. In addition, at the light reception side, it is possible to shield the light from the light emitting element 3 or a disturbance by the optical waveguide plate 32, which is preferably made of a light shielding resin. Thus, it is possible to receive only required light by the light receiving element 4, and it is possible to reduce noise.

The optical waveguides 33 and 34 are able to pass light only through core portions located within the through holes 32A and 32B. That is, it is possible to confine the light in the core portions. The light advances within the core portions while repeating total reflection. For example, when an area of light is to be confined by a light shielding resin or other suitable structure in a state without a waveguide structure, it is impossible to confine the light, unlike with a waveguide. Thus, the light enters the light shielding resin and disappears, so that the energy efficiency decreases. In order to reduce or prevent attenuation of the light, it is necessary to expand the area of light as much as possible, which leads to an increase in the size of the sensor.

In the optical waveguides 33 and 34, it is possible to freely change the core diameter and the shape. Thus, for example, when the core diameter is decreased, it is possible to increase the light amount per unit area, so that it is possible to increase the light beam density. In addition, it is possible to change the numerical aperture (NA) on the basis of the refractive index difference between a core and a clad, and thus it is possible to adjust an emission spread angle and a light reception angle to some extent. For example, when the light reception angle is decreased, as light other than reflected light from a living body, the optical sensor 31 is also able to reduce or prevent disturbance light or the light entering the optical sensor 31 through the lateral side thereof, to some extent.

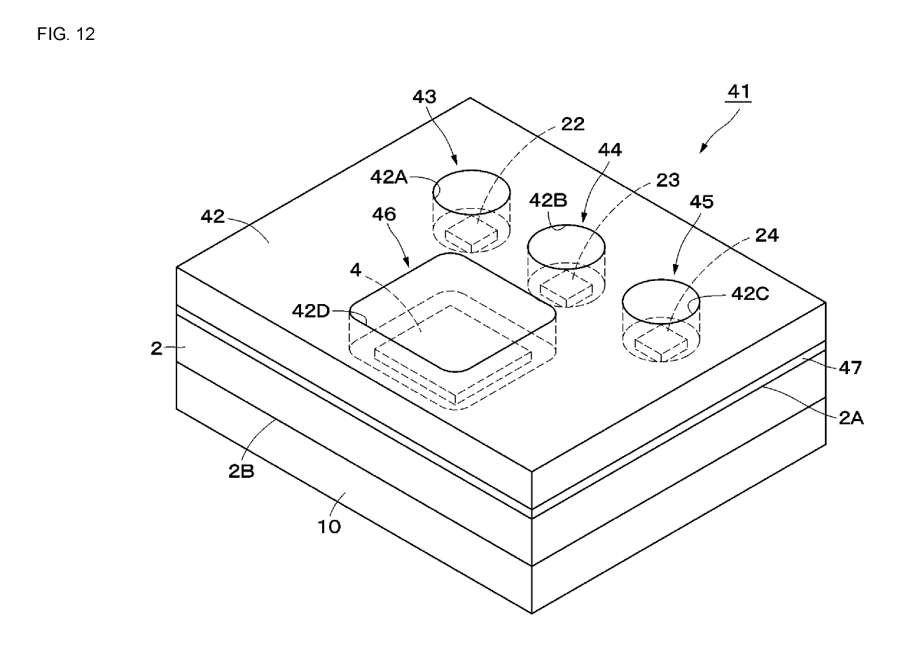

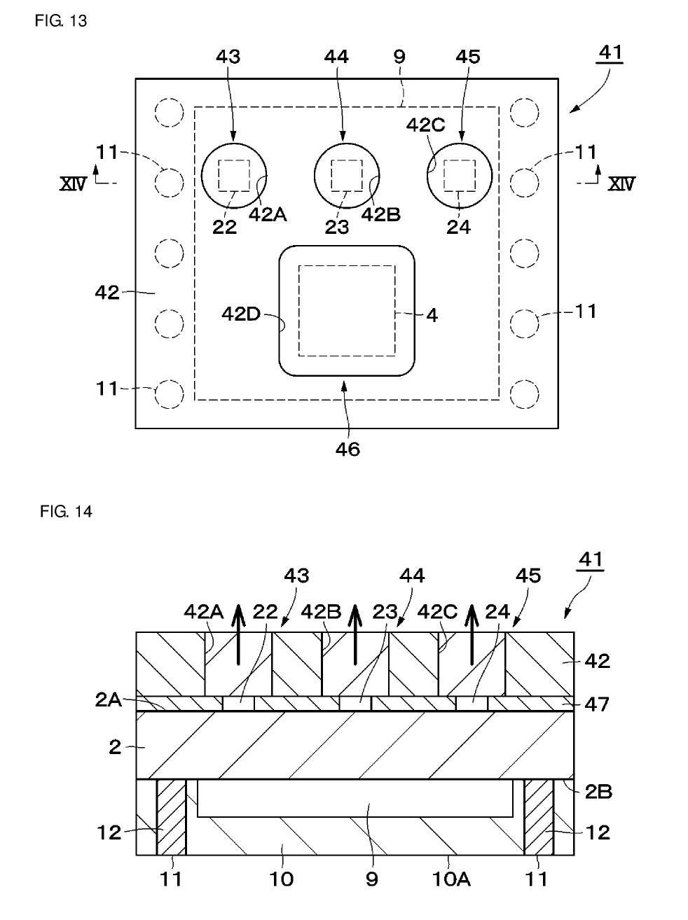

Similarly to the first preferred embodiment, the third preferred embodiment has been described with respect to an application to the optical sensor 31, which includes the one light emitting element 3 and the one light receiving element 4, as an example. The present invention is not limited thereto. For example, as in a modification of a preferred embodiment shown in FIGS. 12 to 14, similarly to the second preferred embodiment, the present invention may be applied to an optical sensor 41 that includes a plurality of (for example, three) light emitting elements 22 to 24 and one light receiving element 4. In this case, an optical waveguide plate 42 includes a plurality of (for example, three) light emission side optical waveguides 43 to 45 corresponding to the plurality of (for example, three) light emitting elements 22 to 24, and one light reception side optical waveguide 46 corresponding to the one light receiving element 4.

In this case, the optical waveguide plate 42 includes through holes 42A to 42C at positions corresponding to the light emitting elements 22 to 24, and includes a through hole 42D provided at a position corresponding to the light receiving element 4. The optical waveguides 43 to 46 are preferably formed by filling these through holes 42A to 42D with a transparent resin material having a high refractive index. The optical waveguide plate 42 is mounted at the front surface 2A side of the substrate 2 with a joint layer 47 interposed therebetween.

The number of the light emitting elements and the number of the light receiving elements are not limited to those shown in the third preferred embodiment or the modification, and, for example, an arbitrary number is selectable in accordance with the purpose and application of the optical sensor.

Each of the above preferred embodiments has been described as being applied to the optical sensor 1, 21, or 31, which detects the photoplethysmographic signal of the living body, as an example. The present invention is not limited thereto. For example, the present invention is applicable to various optical sensors that detect reflected light from a measurement object, such as a proximity sensor. When a preferred embodiment of the present invention is applied to a proximity sensor, since the light receiving element and the electrical component are components separate from each other, it is possible to change the size of the light receiving element in accordance with required sensitivity as appropriate.

Each preferred embodiment of the present invention is merely illustrative, and the components shown in the different preferred embodiments may be partially replaced or combined.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An optical sensor comprising:
a substrate;
a light emitting element mounted on a front surface of the substrate;
a light receiving element mounted on the front surface of the substrate; and
an electrical component mounted on a back surface of the substrate and electrically connected to the light emitting element and the light receiving element; wherein
the electrical component is located at a position overlapping the light emitting element and the light receiving element in plan view.

2. The optical sensor according to claim 1, further comprising:
a frame provided at a side of the front surface of the substrate and structured to shield light between the light emitting element and the light receiving element; and
a transparent resin portion covering the light emitting element and the light receiving element.

3. The optical sensor according to claim 1, further comprising:
an optical waveguide plate provided at a side of the front surface of the substrate and covering the light emitting element and the light receiving element; wherein
the optical waveguide plate includes a light emission side optical waveguide that guides light from the light emitting element to the outside, and a light reception side optical waveguide that guides external light to the light receiving element.

4. The optical sensor according to claim 1, further comprising:
a bottom portion provided at a side of the back surface of the substrate, covering the electrical component, and made of a resin material; and
an electrode terminal provided on a back surface of the bottom portion and electrically connected to the electronic component.

5. The optical sensor according to claim 1, wherein the substrate is a multilayer substrate including a plurality of electrode layers and a plurality of insulating layers that are alternately laminated.

6. The optical sensor according to claim 1, wherein the light emitting element is one of a light emitting diode, a laser diode, a vertical-cavity surface-emitting laser, or a resonant LED.

7. The optical sensor according to claim 1, wherein The light emitting element emits light in a 500 nm to 1000 nm band.

8. The optical sensor according to claim 1, wherein the light receiving element is a photodiode.

9. The optical sensor according to claim 2, wherein the frame is black and made of a non-transparent resin material.

10. The optical sensor according to claim 4, further comprising:
columnar conductor pins provided on the back surface of the substrate and extending through the bottom portion; wherein
a proximal end surface of each of the conductor pins is fixed to the substrate and electrically connected to the electrical component; and
a distal end surface of each of the conductor pins is exposed on a back surface of the bottom portion and defines the electrode terminal.

11. An optical sensor comprising:
a substrate;
a plurality of light emitting elements mounted on a front surface of the substrate;
a light receiving element mounted on the front surface of the substrate; and
an electrical component mounted on a back surface of the substrate and electrically connected to the plurality of light emitting elements and the light receiving element; wherein
the electrical component is located at a position overlapping the plurality of light emitting elements and the light receiving element in plan view.

12. The optical sensor according to claim 11, further comprising:
a frame provided at a side of the front surface of the substrate and structured to shield light between the plurality of light emitting elements and the light receiving element; and
a transparent resin portion covering the plurality of light emitting elements and the light receiving element.

13. The optical sensor according to claim 11, further comprising:
an optical waveguide plate provided at a side of the front surface of the substrate and covering the plurality of light emitting elements and the light receiving element; wherein
the optical waveguide plate includes a plurality of light emission side optical waveguides that guide light from the plurality of light emitting elements to the outside, and a light reception side optical waveguide that guides external light to the light receiving element.

14. The optical sensor according to claim 11, further comprising:
a bottom portion provided at a side of the back surface of the substrate, covering the electrical component, and made of a resin material; and
an electrode terminal provided on a back surface of the bottom portion and electrically connected to the electronic component.

15. The optical sensor according to claim 11, wherein the substrate is a multilayer substrate including a plurality of electrode layers and a plurality of insulating layers that are alternately laminated.

16. The optical sensor according to claim 11, wherein each of the plurality of light emitting elements is one of a light emitting diode, a laser diode, a vertical-cavity surface-emitting laser, or a resonant LED.

17. The optical sensor according to claim 11, wherein each of the plurality of light emitting elements emits light in a 500 nm to 1000 nm band.

18. The optical sensor according to claim 11, wherein the light receiving element is a photodiode.

19. The optical sensor according to claim 12, wherein the frame is black and made of a non-transparent resin material.

20. The optical sensor according to claim 14, further comprising:
columnar conductor pins provided on the back surface of the substrate and extending through the bottom portion; wherein
a proximal end surface of each of the conductor pins is fixed to the substrate and electrically connected to the electrical component; and
a distal end surface of each of the conductor pins is exposed on a back surface of the bottom portion and defines the electrode terminal.
